(19) United States
(12) Patent Application Publication
(10) Pub. No.: US 2026/0133233 A1
(43) Pub. Date: May 14, 2026

(54) MULTI-CHANNEL SIGNAL AND POWER ANALYZER

(71) Applicant: Tektronix, Inc., Beaverton, OR (US)

(72) Inventor: Kan Tan, Portland, OR (US)

(21) Appl. No.: 19/378,172

(22) Filed: Nov. 3, 2025

Related U.S. Application Data
(60) Provisional application No. 63/718,480, filed on Nov. 8, 2024.

(51) Int. Cl. G01R 29/08; G01R 13/02; G01R 31/28

(52) U.S. Cl. CPC G01R 29/0871; G01R 13/0272; G01R 13/029; G01R 31/2822

(57) ABSTRACT

A signal and power analysis instrument includes one or more high-bandwidth input channels configured as one or more real-equivalent time (RET) input channels and/or one or more radio frequency (RF) channels, one or more input channels configured as one or more low-bandwidth real-time (RT) input channels, one or more analog-to-digital converters (ADCs) having pipes, a first set of pipes connected to the one or more high-bandwidth input channels to produce high-bandwidth data, and a second set of the pipes connected to the one or more low-bandwidth RT input channels to produce low-bandwidth RT data, a system clock connected to high-bandwidth input channels and the low-bandwidth RT input channels, a memory connected to the system clock, the first set of pipes, and the second set pipes, and one or more processors to store low-bandwidth RT data and high-bandwidth data in the memory, and align the high-bandwidth data and the low-bandwidth data.

### CROSS-REFERENCE TO RELATED APPLICATIONS

This disclosure is a non-provisional of and claims benefit from U.S. Provisional Application No. 63/718,480, titled “MULTI-CHANNEL SIGNAL AND POWER ANALYZER,” filed on November 8, 2024, the disclosure of which is incorporated herein by reference in its entirety.

### TECHNICAL FIELD

This disclosure relates to test and measurement instruments, and more particularly to a multi-channel combined signal and power analyzer instrument.

### BACKGROUND

With the progression of generative AI, data center, electrical vehicle (EV), 5G/6G wireless, quantum computing, the needs are rising for an instrument that has high channel counts and can perform combined signal integrity (SI) and power integrity (PI) analysis. Higher speed wired data transfer enables generative AI and data center to handle increased demand on data, higher power is required to support the data transfer and data processing. Industry standards such as IEEE Ethernet 800G require high analog bandwidth oscilloscopes to measure its signal integrity. Power supplies require oscilloscopes with much lower analog bandwidth to measure power integrity. Since there are correlations between signal integrity (SI) and power integrity (PI), a single instrument that can capture the time correlated signals for the SI/PI analysis will enable users to gain greater insights of their designs. EV, 5G/6G wireless and quantum computing all have the unmet needs to have a single instrument to capture and analyze time-correlated time domain signals, RF signals, and power supply signals.

The need for such instruments comes from several areas. The advancement of generative AI triggered significant development of high-performance computation infrastructure including clusters of GPUs for LLM training, and large data centers to provide data storage, process, and transfer. These applications demand higher power. The adoption of electrical vehicle (EV) globally increases the need for power analysis instruments. Modern vehicles are equipped with high speed wired and wireless data communication systems to transfer video, radar, and other sensor data. More qubits are being built into quantum computing systems, hundreds and thousands of qubits in a quantum computer require spectrum analyzers with high channel counts. 5G and 6G wireless testing requires spectrum analyzers with higher channel counts because of their massive multi-input-multi-output (MIMO) architectures.

Signal integrity (SI) analysis is needed for the high-speed time domain signals such as the 800G PAM4 Ethernet signal, and for the high bandwidth RF signal such as 5G and 6G wireless signals. Power integrity (PI) analysis is needed for power supplies and electrical motors. The interaction between the power supply and signal path requires SI/PI analysis. The SI/PI analysis is initially performed with simulation during system design phase. When the actual systems are produced, test instruments are used to verify the design and to debug the system.

U.S. Pat. No. 11,789,051, titled “Real-equivalent-time oscilloscope,” issued October 17, 2023, the contents of which are hereby incorporated by reference into this disclosure in its entirety, describes a new class of oscilloscope, the real-equivalent-time (RET) oscilloscope. The RET oscilloscope uses only a single ADC with lower sample rate per channel thereby greatly reducing the complexity and cost compared to a conventional real-time oscilloscope which typically has multiple ADC interleaved to reach higher sample rate. U.S. Pat. App. Pub. No. 2024/0313795, titled “Real-Equivalent-Time oscilloscope and Wideband Real-Time Spectrum Analyzer,” filed February 29, 2024, the contents of which are incorporated by reference into this disclosure in its entirety, describes a new class of instrument that leverages the RET oscilloscope architecture described in U.S. Pat. No. 11,789,051 to enable the instrument to also operate as a real-time spectrum analyzer. Embodiments of this disclosure utilize the technology described in U.S. Pat. No. 11,789,051 and U.S. Pat. App. Pub. No. 2024/0313795.

### BRIEF DESCRIPTION OF THE DRAWINGS

FIG. 1 shows an embodiment of a signal and power analysis instrument.

FIG. 2 shows a block diagram of an embodiment of signal and power analysis.

FIG. 3 shows a block diagram of an embodiment of a channel architecture of a signal and power analysis instrument.

FIG. 4 shows an example of spectrogram of a signal resulting from a power integrity issue.

### DETAILED DESCRIPTION

The embodiments here involve a new instrument referred to here as a Signal and Power Analyzer (SPA). Generally, the SPA will have higher channel counts, its system clock allows synchronized signal capture across all channels, and each channel of the instrument can be configured to be a high analog bandwidth equivalent-time sampling oscilloscope channel, a high bandwidth real-time spectrum analyzer channel, or a lower analog bandwidth real-time oscilloscope channel. The unique architecture of SPA enables high channel density, lower cost, and lower power consumption. A single SPA unit serves both the power market and the wired and wireless data communication market.

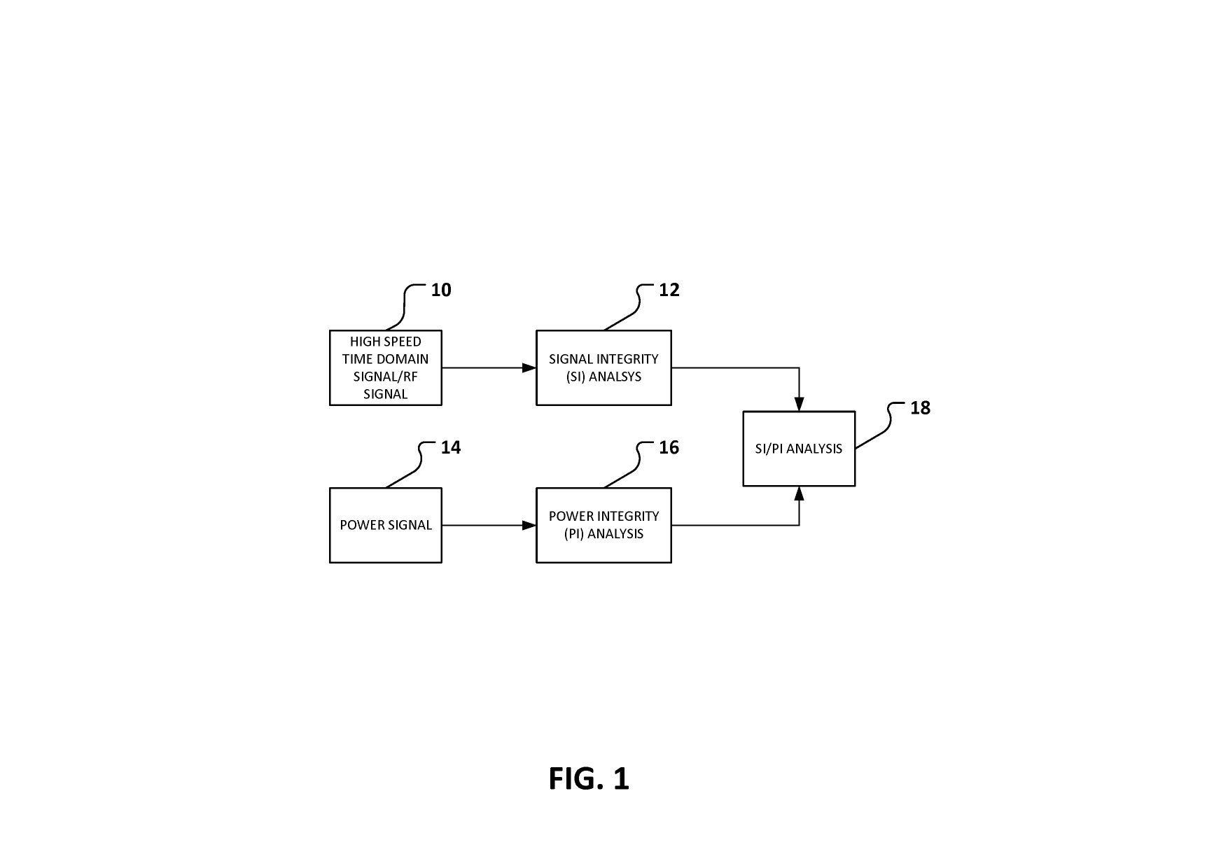

The SPA has many uses, but one particular application involves the use of a combined analysis of both signal and power integrity at the same moments in time. As shown in FIG. 1, the ability to perform signal integrity analysis and power integrity analysis in a combined fashion allows designers the ability to understand the effects of power integrity issues on the signals. High-speed time domain signals 10 such as the 800G PAM4 Ethernet signal, and the high bandwidth RF signal such as 5G and 6G wireless signals 10 require signal integrity (SI) analysis 12. Power supplies and electric motors that generate power signals 14 need power integrity (PI) analysis 16. The interaction between the power supply and signal path requires SI/PI analysis 18. The SI/PI analysis initially occurs with simulation during system design phase. When the actual systems operate, currently two different instruments, such as a higher bandwidth real-time oscilloscope for the signal capture, and a lower bandwidth real-time oscilloscope for the power signal, are needed. Since two separation instruments are used, it is challenging to get a precise time-correlated view on the two instruments.

The embodiments here involve more than just a combination of two separate instruments. They provide alignment in time for time-domain and frequency-domain signals to allow designers to understand the effects the power and data signals have on each other, providing designers with the ability to build and troubleshoot more robust systems.

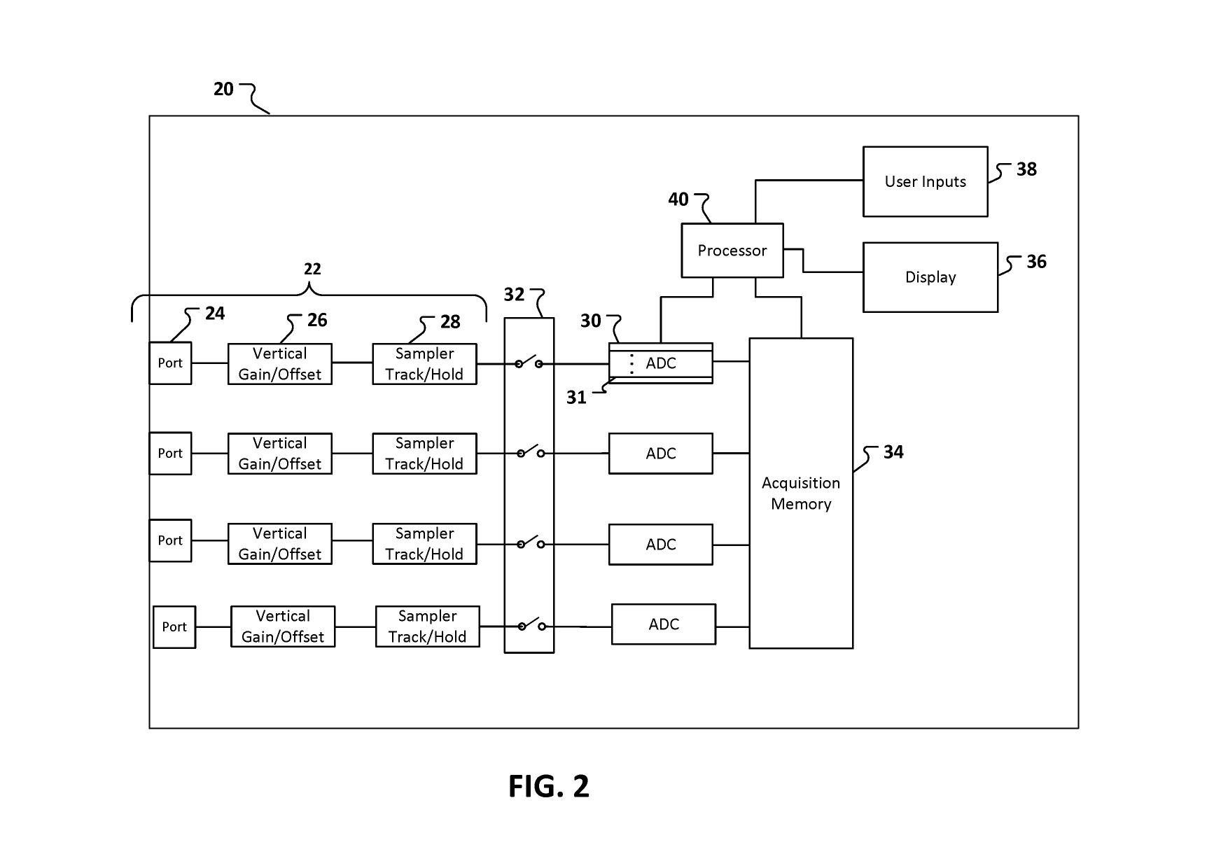

FIG. 2 shows a diagram of one embodiment of an SPA test and measurement instrument. The instrument 20 includes one or more ports such as 24 which may be any electrical or optical signaling medium. Ports such as 24 may include receivers, transmitters, and/or transceivers. Each port 24 comprises a channel of the test and measurement instrument. The structures encompassed by 22 are replicated for each channel of the instrument.

The signals from the ports are then sent to a vertical offset 26 that can adjust the offset or baseline of the received signal. In some configurations or examples, the vertical gain/offset 26 may also include a vertical gain adjustment. If there is no vertical gain adjustment, vertical noise can be reduced, but there is also a decrease in the dynamic range. To address this, in some examples, an external attenuator and/or amplifier may be used to attenuate and/or amplify the incoming signal under test. The signal is sent to a sampler track and hold circuit 28 from the vertical gain/offset 26. The track and hold circuit 28 samples and holds each signal steady for a period of time sufficient to enable acquisition by an analog-to-digital converter (ADC) such as 30.

In the embodiments here the ADC 30 is one of a group of one or more ADCs. The ADCs comprise a “pool” of ADCs, each of which may have one or more “pipes” such as 31. The embodiments here treat ADC pipes as independent ADCs, can connect to channels in various configurations typically controlled by processor 40. In an example of currently available oscilloscopes, a 4-channel real-time (RT) oscilloscope with total of 100 GS/s (Gigasamples/second) ADC, if users turn on all 4 channels, each channel gets 100/4 = 25GS/s. If users turn on only 2 channels, each channel can get 100/2 = 50GS/s. In the instrument of the embodiments, there are wires and switches, such as the switch array 32, that enable various channels and ADC paths.

The ADC 30 converts the analog data signal and or the power signal from the track and hold circuit 28 to digital signal data and power data. The digitized signal from the ADC converter 30 can then be stored in an acquisition memory 34. The ADC 30 could be a single high-resolution ADC, such as a 12-bit analog-to-digital converter with multiple pipes. The different channels may connect to multiple pipes such as 31 in one ADC, or multiple pipes across different ADCs. The embodiments do not require any particular configuration of ADCs and pipes

One or more processors 40 may be configured to execute instructions from memory and may perform any methods and/or associated steps indicated by such instructions, such as receiving the acquired signals from the acquisition memory 34 and reconstructing the signal under test without the use of a hardware trigger or acquiring the sample in the high sample rate.

Memory 34 or any other memory on the test and measurement instrument 20 may be implemented as processor cache, random access memory (RAM), read only memory (ROM), solid state memory, hard disk drive(s), or any other memory type. Memory acts as a medium for storing data, computer program products, and other instructions.

User inputs 38 are coupled to one or more processors 40. User inputs 38 may include a keyboard, mouse, trackball, touchscreen, and/or any other controls employable by a user to interact with a GUI on display 36. Display 36 may be a digital screen, a cathode ray tube-based display, or any other monitor to display waveforms, measurements, and other data to a user. While the components of the test and measurement instrument are depicted as being integrated within test and measurement instrument 20, it will be appreciated by a person of ordinary skill in the art that any of these components can be external to the test and measurement instrument 20 and can be coupled to the test and measurement instrument 20 in any conventional manner, such as wired and/or wireless communication media and/or mechanisms. For example, in some examples, display 36 may be remote from the test and measurement instrument 20.

The SPA embodiments have configurable channels. The configurations are of four different types. The system may have one or more real-time (RT) channels. Each RT channel may comprise a high sampling rate/high-bandwidth channel, or a low sampling rate/low bandwidth-channel as two of the RT channel types. High-bandwidth RT channels require a large number of ADCs. The low-bandwidth RT channels require a lower number of ADCs, The real-equivalent-time (RET) channels that have high bandwidth and low sampling rates comprise a third type. A fourth type of channel is a radio frequency (RF) channel that has high bandwidth and low sample rate. High-bandwidth RT channels generally digitize an entire waveform in one pass, using one or more ADCs that have a sample rate high enough to capture the signal in real time. RET channels have low sampling rates and high bandwidth. They generally sample the incoming signal at a sampling rate below the Nyquist frequency required value over multiple iterations of a repeating pattern, then perform software clock recovery and reconstruct the signal in the equivalent time sense. RF channels will generally need at least two pipes at a low sample rate to digitize the incoming signal with high bandwidth.

The SPA is configured to have one or more high-bandwidth channels comprised of at least one or more RET channels and one or more RF channels, and a low-bandwidth RT channel. The SPA may have one or both the RET and the RF channels combined with one or more low-bandwidth RT channel. In another embodiment, the high-bandwidth channels include a high-bandwidth RT channel. The high-bandwidth channels may comprise a combination of RET and RF channel(s), RET and high-bandwidth RT channel(s), RF and high-bandwidth RT channel(s), or RET, RF, and high-bandwidth RT channel(s). The high-bandwidth channels of whatever configuration are combined with the low-bandwidth RT channel(s).

For ease of understanding one can consider this example. The high-bandwidth RT channel's sampler connects to a set of multiple ADCs or pipes. In one example, one could assume 16 pipes either from one ADC or from multiple ADCs. The 16 pipes may be interleaved to provide the high combined ADC sample rate for the high-bandwidth RT channel. The RET channel's sampler connects to a second set of pipes or ADCs, where the set may comprise one or just a few ADC pipes, the combined ADC sample rate is much lower than that of the high-bandwidth RT channel. The RET channel can support the sample high analog bandwidth as the RT channel. The instrument of the embodiments provides multiple channels that can be configured as RET channels, RF channels, low-bandwidth RT channels, and high-bandwidth RT channels. For signal and power analysis, the low-bandwidth RT channels, may connect to the power signal from the device under test (DUT), or from a power supply that provides power to the DUT. The RET, RF, and high-bandwidth RT channels may connect to the data signal(s) from the DUT. The combination of the two inputs allows for the combined power integrity/signal integrity analysis.

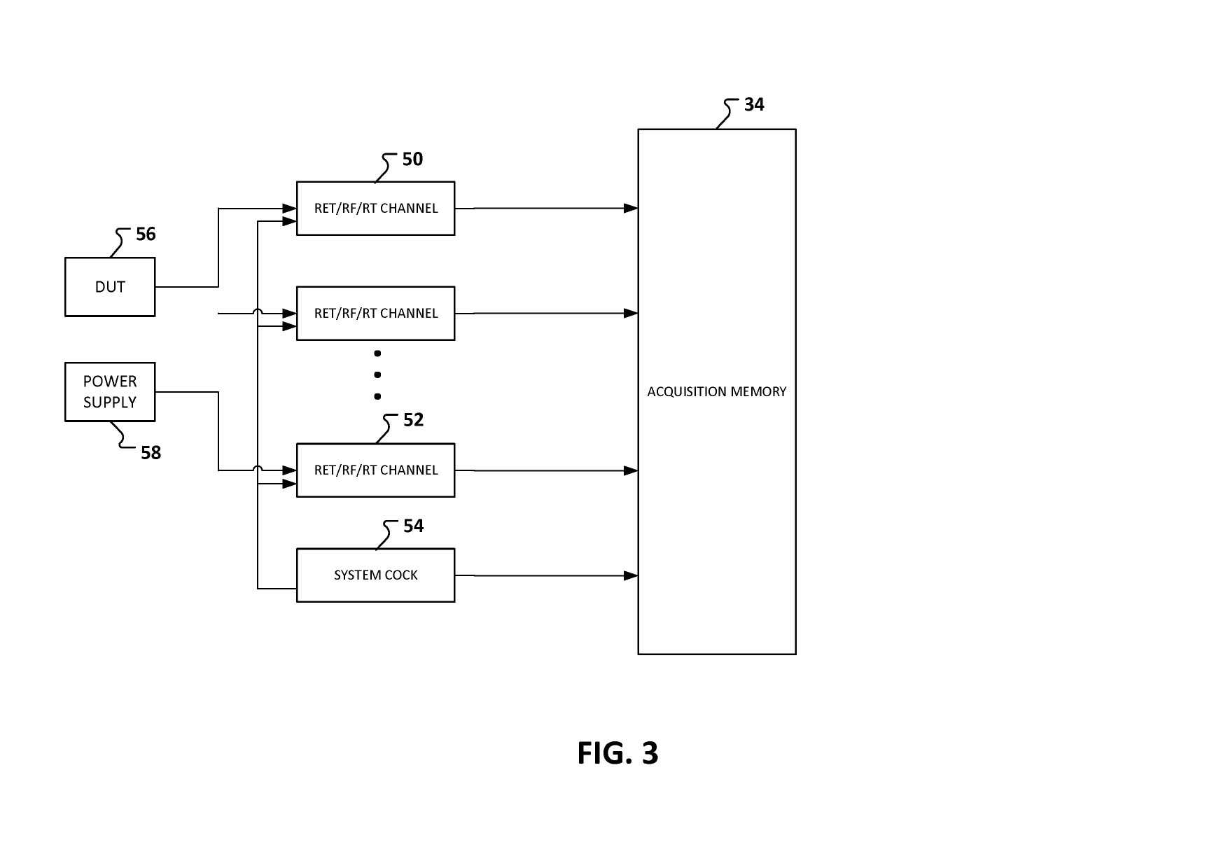

FIG. 3 shows an embodiment of a general architecture of the multi-channel SPA instrument, according to embodiments of the disclosure. Since the lower ADC sample rate supports the RET/RF channels, they require fewer hardware components and consume less power. Therefore, one SPA instrument can contain multiple channels. SPA may have a higher channel count than a same sized RT oscilloscope, or a same sized RT spectrum analyzer with the same analog bandwidth. The RET/RF channels are used for signal integrity (SI) analysis. Each channel such as 50 and 52 can also be configured as a real-time (RT) channel like a regular real-time oscilloscope channel. The low bandwidth RT channels can be used for power integrity (PI) analysis. Since the system clock 54 drives all channels in the instrument, all channel acquisitions are synchronized. The system clock information is saved in acquisition memory 34 with the acquired channel data. The time correlated acquisition data with system clock 54 information enables accurate and coherent real-time combined SI/PI analysis.

As an example, a device under test (DUT) 56 could be connected to a first of the channels, 50, which in this example is configured as a RET data input channel for signal integrity. This will allow the channel to function at high analog bandwidth and capture the data signal. The ADC and/or ADC pipes such as those shown in FIG. 2 will then convert the data signal to signal data. The one or more processors would then reconstruct the complete data for the signal data and store it in the memory. Meanwhile, the power supply 58 is connected to an input channel configured as the low analog bandwidth RT channel to capture the power signal, which will then be converted to power data, to differentiate it from the signal data that is from the DUT. The power supply 58 may reside on the DUT or may comprise an external power supply. Each channel will have a set of ADCs or ADC pipes connected to it, with RT high-bandwidth channels having a higher number of ADCs than the RET and RF channels and possibly the RT low-bandwidth channel. As an example, the high-bandwidth RT channel requires 64 pipes, the RET channel requires 1 pipe, and the RF channel requires 2 pipes. The high-bandwidth RT channel requires many more pipes than RET or RF channels.

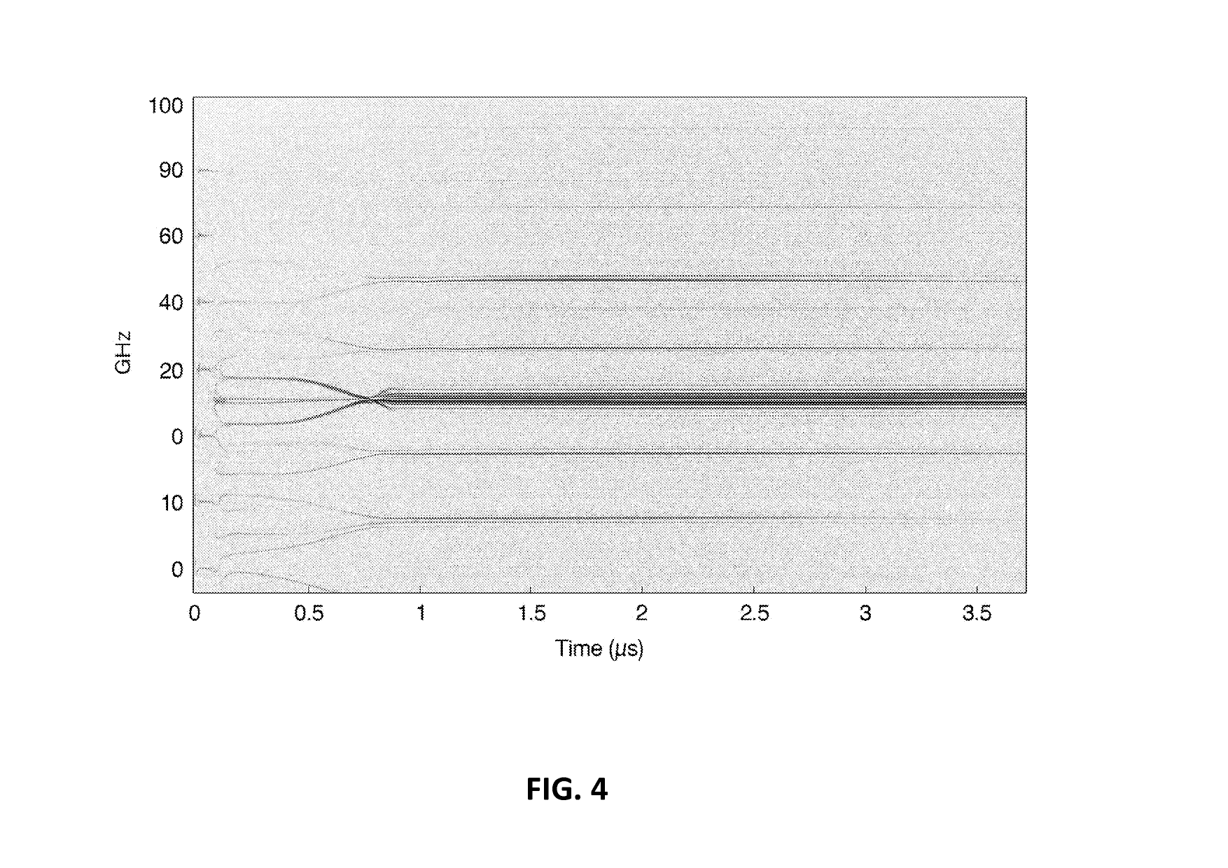

FIG. 4 shows an example of a situation in which the SPA would provide many benefits to the design. The spectrogram plot shows the unexpected transient responses of an oscillator that happened before 1.2us mark in time (horizontal axis). The data for the spectrogram plot was captured by a high bandwidth real-time oscilloscope. It took some time before the designer figured out that the transient responses were caused by a power supply issue. The designer had to debug the power supply by using a second, lower bandwidth, real-time oscilloscope. The SPA embodiments described herein can quickly identify the issues with confidence. The power supply issue and the transient responses of the oscillator can be captured in a time-correlated manner. The triggers in time domain or frequency domain can be used to align the signal data and the power data to help users capture the anomalies quickly.

The embodiments herein disclose a new SPA instrument. The SPA provides higher channel count in one instrument and provides time-correlated acquisitions that enable real-time combined SI/PI analysis.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a signal and power analysis instrument, comprising: one or more high-bandwidth input channels configured as at least one of one or more real-equivalent time (RET) input channels or one or more radio frequency (RF) channels connected to a device under test DUT; one or more input channels configured as one or more low-bandwidth real-time (RT) input channels; one or more analog-to-digital converters (ADCs), each ADC having one or more pipes, a first set of the one or more pipes connected to the one or more high-bandwidth input channels to produce high-bandwidth data, and a second set of the one or more pipes connected to the one or more low-bandwidth RT input channels to produce low-bandwidth data; a system clock connected to the one or more high-bandwidth input channels, and the one or more low-bandwidth RT input channels; a memory connected to the system clock, the first set of the one or more pipes connected to the one or more high-bandwidth input channels, and the second set of one or more pipes connected to the one or more low-bandwidth RT input channels; and one or more processors configured to execute code that causes the one or more processors to: store low-bandwidth data from the second set of pipes in the memory; store high-bandwidth data from the first set of pipes in the memory; and align the high-bandwidth data and the low-bandwidth data in time using the system clock.

Example 2 is the signal and power analysis instrument of Example 1, wherein the one or more high-bandwidth input channels comprise one or more RET input channels and one or more RF input channels, only RET input channels, or only RF input channels.

Example 3 is the signal and power analysis instrument of either of Examples 1 or 2, wherein the one or more high-bandwidth input channels further comprises one or more high-bandwidth RT input signal channels, and the instrument further comprises a third set of pipes connected to the one or more high-bandwidth RT input signal channels.

Example 4 is the signal and power analysis instrument of Example 3, wherein the one or more high-bandwidth input channels comprise one or more RET input channels and one or more high-bandwidth RT input channels, one or more RF input channels and one or more high-bandwidth RT channels, or one or more RET input channels, one or more RF input channels, and one or more high-bandwidth RT input channels.

Example 5 is the signal and power analysis instrument of Example 3, wherein the one or more high-bandwidth input channels comprise one or more RET input channels and a first set of pipes comprises fewer pipes than a number of pipes in the third set of pipes.

Example 6 is the signal and power analysis instrument of any of Examples 1 through 5, wherein the one or more high-bandwidth input channels are configured to receive one or more signals from the DUT, and the high-bandwidth data comprises signal data.

Example 7 is the signal and power analysis instrument of Example 6, wherein the one or more low-bandwidth RT input channels are configured to connect to a power supply that provides power to the DUT, and the low-bandwidth RT data comprises power data.

Example 8 is the signal and power analysis instrument of Example 7, wherein the code that causes the one or more processors to align the high-bandwidth data and the low-bandwidth data in time comprises code to align the power data and the signal data by using the system clock.

Example 9 is the signal and power analysis instrument of Example 6, wherein the signal data comprises at least one of RET data and RF data.

Example 10 is the signal and power analysis instrument of Example 6, wherein the signal data comprises at least one of RET, RF, and high-bandwidth RT data.

Example 11 is a method of performing signal integrity and power integrity analysis, comprising: receiving one or more signals from one or more input channels configured as one or more low-bandwidth real-time (RT) input channels; receiving one or more signals from a device under test (DUT) from one or more high-bandwidth input channels configured as one or more of real-equivalent-time (RET) input channels and radio frequency (RF) input channels; using a first set of one or more analog-to-digital converter pipes (ADC) connected to the one or more low-bandwidth RT input channels to produce low-bandwidth RT data; using a second set of the one or more ADC pipes connected to the one or more high-bandwidth input channels to produce high-bandwidth data; storing the high-bandwidth data and the low-bandwidth RT data in an acquisition memory; and aligning the low-bandwidth RT data and the high-bandwidth data in time using a system clock.

Example 12 is the method of Example 11, wherein receiving signals from the one or more high-bandwidth input channels comprises one or more of receiving signals from the one or more RET input channels and the one or more RF input channels, receiving signals from only the one or more RET input channels, or from only the one or more RF input channels.

Example 13 is the method of either of Examples 11 or 12, further comprising receiving one or more signals from one or more high-bandwidth RT input channels, and using a third set of ADC pipes connected to the one or more high-bandwidth RT input channels.

Example 14 is the method of Example 13, wherein receiving one or more signals from the one or more high bandwidth channels may comprise one or more of receiving one or more signals from the one or more RET input channels and the one or more high-bandwidth RT input channels, the one or more RF input channels and the one or more high-bandwidth RT channels, or the one or more RET input channels, the one or more RF input channels, and the one or more high-bandwidth RT input channels.

Example 15 is the method of Example 13, wherein the one or more high-bandwidth input channels comprises one or more RET input channels and the first set of pipes comprises fewer pipes than a number of pipes in the third set of pipes.

Example 16 is the method of Example 13, wherein receiving the one or more signals from the DUT comprises receiving one or more signals of at least one of RET, RF, and high-bandwidth RT signals.

Example 17 is the method of any of Examples 11 through 16, wherein receiving one or more signals from the DUT from the one or more high-bandwidth input channels comprises receiving signal data.

Example 18 is the method of Example 17, wherein receiving one or more signals from the one or more low bandwidth RT input channels comprises receiving one or more signals from a power supply that provides power to the DUT, and the receiving the one or more signals from the one or more low bandwidth RT channels comprises receiving power data.

Example 19 is the method of Example 18, wherein aligning the low bandwidth RT data and the high-bandwidth data in time comprises aligning the power data and the signal data.

Example 20 is the method of Example 19, further comprising performing signal integrity and power integrity analysis on the time-aligned power data and signal data.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

1. A signal and power analysis instrument, comprising:
one or more high-bandwidth input channels configured as at least one of one or more real-equivalent time (RET) input channels or one or more radio frequency (RF) channels connected to a device under test DUT;
one or more input channels configured as one or more low-bandwidth real-time (RT) input channels;
one or more analog-to-digital converters (ADCs), each ADC having one or more pipes, a first set of the one or more pipes connected to the one or more high-bandwidth input channels to produce high-bandwidth data, and a second set of the one or more pipes connected to the one or more low-bandwidth RT input channels to produce low-bandwidth data;
a system clock connected to the one or more high-bandwidth input channels, and the one or more low-bandwidth RT input channels;
a memory connected to the system clock, the first set of the one or more pipes connected to the one or more high-bandwidth input channels, and the second set of one or more pipes connected to the one or more low-bandwidth RT input channels; and
one or more processors configured to execute code that causes the one or more processors to:
store low-bandwidth data from the second set of pipes in the memory;
store high-bandwidth data from the first set of pipes in the memory; and
align the high-bandwidth data and the low-bandwidth data in time using the system clock.

2. The signal and power analysis instrument as claimed in claim 1, wherein the one or more high-bandwidth input channels comprise one or more RET input channels and one or more RF input channels, only RET input channels, or only RF input channels.

3. The signal and power analysis instrument as claimed in claim 1, wherein the one or more high-bandwidth input channels further comprises one or more high-bandwidth RT input signal channels, and the instrument further comprises a third set of pipes connected to the one or more high-bandwidth RT input signal channels.

4. The signal and power analysis instrument as claimed in claim 3, wherein the one or more high-bandwidth input channels comprise one or more RET input channels and one or more high-bandwidth RT input channels, one or more RF input channels and one or more high-bandwidth RT channels, or one or more RET input channels, one or more RF input channels, and one or more high-bandwidth RT input channels.

5. The signal and power analysis instrument as claimed in claim 3, wherein the one or more high-bandwidth input channels comprise one or more RET input channels and a first set of pipes comprises fewer pipes than a number of pipes in the third set of pipes.

6. The signal and power analysis instrument as claimed in claim 1, wherein the one or more high-bandwidth input channels are configured to receive one or more signals from the DUT, and the high-bandwidth data comprises signal data.

7. The signal and power analysis instrument as claimed in claim 6, wherein the one or more low-bandwidth RT input channels are configured to connect to a power supply that provides power to the DUT, and the low-bandwidth data comprises power data.

8. The signal and power analysis instrument as claimed in claim 7, wherein the code that causes the one or more processors to align the high-bandwidth data and the low-bandwidth data in time comprises code to align the power data and the signal data by using the system clock.

9. The signal and power analysis instrument as claimed in claim 6, wherein the signal data comprises at least one of RET data and RF data.

10. The signal and power analysis instrument as claimed in claim 6, wherein the signal data comprises at least one of RET, RF, and high-bandwidth RT data.

11. A method of performing signal integrity and power integrity analysis, comprising:
receiving one or more signals from one or more input channels configured as one or more low-bandwidth real-time (RT) input channels;
receiving one or more signals from a device under test (DUT) from one or more high-bandwidth input channels configured as one or more of real-equivalent-time (RET) input channels and radio frequency (RF) input channels;
using a first set of one or more analog-to-digital converter pipes (ADC) connected to the one or more low-bandwidth RT input channels to produce low-bandwidth RT data;
using a second set of the one or more ADC pipes connected to the one or more high-bandwidth input channels to produce high-bandwidth data;
storing the high-bandwidth data and the low-bandwidth RT data in an acquisition memory; and
aligning the low-bandwidth RT data and the high-bandwidth data in time using a system clock.

12. The method as claimed in claim 11, wherein receiving signals from the one or more high-bandwidth input channels comprises one or more of receiving signals from the one or more RET input channels and the one or more RF input channels, receiving signals from only the one or more RET input channels, or from only the one or more RF input channels.

13. The method as claimed in claim 11, further comprising receiving one or more signals from one or more high-bandwidth RT input channels, and using a third set of ADC pipes connected to the one or more high-bandwidth RT input channels.

14. The method as claimed in claim 13, wherein receiving one or more signals from the one or more high bandwidth input channels may comprise one or more of receiving one or more signals from the one or more RET input channels and the one or more high-bandwidth RT input channels, the one or more RF input channels and the one or more high-bandwidth RT channels, or the one or more RET input channels, the one or more RF input channels, and the one or more high-bandwidth RT input channels.

15. The method as claimed in claim 13, wherein the one or more high-bandwidth input channels comprises one or more RET input channels and the first set of pipes comprises fewer pipes than a number of pipes in the third set of pipes.

16. The method as claimed in claim 13, wherein receiving the one or more signals from the DUT comprises receiving one or more signals of at least one of RET, RF, and high-bandwidth RT signals.

17. The method as claimed in claim 11, wherein receiving one or more signals from the DUT from the one or more high-bandwidth input channels comprises receiving signal data.

18. The method as claimed in claim 17, wherein receiving one or more signals from the one or more low bandwidth RT input channels comprises receiving one or more signals from a power supply that provides power to the DUT, and the receiving the one or more signals from the one or more low bandwidth RT channels comprises receiving power data.

19. The method as claimed in claim 18, wherein aligning the low bandwidth RT data and the high-bandwidth data in time comprises aligning the power data and the signal data.

20. The method as claimed in claim 19, further comprising performing signal integrity and power integrity analysis on the time-aligned power data and signal data.
